(19) United States
(12) Patent Application Publication
(10) Pub. No.: US 2007/0121295 A1
(43) Pub. Date: May 31, 2007

(54) Hybrid liquid-air cooled module

(75) Inventors: Levi A. Campbell, New Paltz, NY (US); Richard C. Chu, Hopewell Junction, NY (US); Michael J. Ellsworth JR., Lagrangeville, NY (US); Madhusudan K. Iyengar, Kingston, NY (US); Roger R. Schmidt, Poughkeepsie, NY (US); Robert E. Simons, Poughkeepsie, NY (US)

Correspondence Address: Lily Neff;IBM Corporation - MS P386, 2455 South Road, Poughkeepsie, NY, 12601, US

(73) Assignee: International Business Machines Corporation, Armonk, NY (US)

(21) Appl. No.: 11/290,898

(22) Filed: Nov. 30, 2005

(51) Int. Cl. H05K 7/20

(52) U.S. Cl. 361/699

(57) ABSTRACT

A method and incorporated hybrid air and liquid cooled module for cooling electronic components of a computing system is disclosed. The module is used for cooling electronic components and comprise a closed loop liquid cooled assembly in thermal communication with an air cooled assembly, such that the air cooled assembly is at least partially included in the liquid cooled assembly.

### BACKGROUND OF THE INVENTION

1. Field of the Invention

This invention relates to cooling of electronic packages used in -computing system environments and more particularly to cooling of electronic components used in mid-range and high-end high volume servers.

2. Description of Background

The industry trend has been to continuously increase the number of electronic components inside computing system environments. A computing system environment can simply comprise a single personal computer or a complex network of large computers in processing communication with one another. Increasing the components inside a simple computing system environment does create some challenges. Such an increase create many problems in computing system environments that include large computer complexes. In such instances many seemingly isolated issues affect one another, and have to be resolved in consideration with one another. This is particularly challenging in environments where the computers in the network are either packaged in a single assembly or housed and stored in close proximity.

One such particular challenge when designing any computing system environment is the issue of heat dissipation. Heat dissipation if unresolved, can result in electronic and mechanical failures that will affect overall system performance, no matter what the size of the environment. As can be easily understood, the heat dissipation increases as the packaging density increases. In larger computing system environments, however, not only the number of heat generating electronic components are more numerous than that of smaller environments, but thermal management solutions must be provided that take other needs of the system environment into consideration. Improper heat dissipation can create a variety of other seemingly unrelated problems. For example solutions that involve too heavy fans, blowers and other such components may lead to weight issues that can affect the structural rigidity of the computing system environment. In customer sites that house complex or numerous computing system environments, unresolved heat dissipation issues may necessitate other cost prohibitive solutions such as supplying additional air conditioning to the to customer site.

Heat dissipation issues have become a particular challenge in mid to large range computing system environments. FIG. 1, illustrates a prior art example where a heat sink employing a vapor chamber spreader is used for thermal management. The problem with such arrangement is that the technology currently being practiced is reaching the end of its extendability, especially in regard to the newer microprocessor technology that uses metal oxide semiconductor (CMOS) packages. In recent years, current prior art arrangements are having difficulties resolving heat load and local heat flux issues and these have become a critical factor, especially in the design of mid to high-range, high volume server packages.

Consequently, a new and improved cooling arrangement is needed that can meet the current thermal management growing needs and address demands of next generation environments, especially those that incorporate CMOS technology in mid to high range, high volume servers.

### SUMMARY OF THE INVENTION

The shortcomings of the prior art are overcome and additional advantages are provided through the provision of a method and incorporated hybrid air and liquid cooled module. The module is used for cooling electronic components and comprise a closed loop liquid cooled assembly in thermal, and preferably fluid, communication with an air cooled assembly, such that the air cooled assembly is at least partially included in the liquid cooled assembly. In one embodiment, the closed loop liquid cooling assembly includes a heat exchanger, a liquid pump and a cold plate in thermal communication with one another and the air cooled and the liquid cooled assembly are at least partially disposed on an auxiliary drawer which is turn disposed to a side of electronic cooling components. The air cooled assembly comprises the same heat exchanger disposed on one end of an auxiliary drawer and an air moving device disposed on another side of the auxiliary drawer such that air can pass easily from one side of the auxiliary drawer to another side. A liquid pump and a control card is also disposed over the auxiliary drawer between the heat exchanger and the air moving device side.

Additional features and advantages are realized through the techniques of the present invention. Other embodiments and aspects of the invention are described in detail herein and are considered a part of the claimed invention. For a better understanding of the invention with advantages and features, refer to the description and to the drawings.

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1 is a prior art illustration showing an air-cooled server with an air cooled air sink having a vapor chamber base;

FIG. 2a is an illustration of an overall depiction of one embodiment of the present invention; and

FIG. 2b provide a more detailed illustration of the embodiment provided by FIG. 2a;

FIG. 3a and 3b respectively illustrate the airflow and liquid flow cooling features as provided by the hybrid module of previous figures;

FIGS. 4 is an illustration of an alternate embodiments of the present invention;

FIG. 5 provide a more detailed illustration of the alternate embodiment of FIG. 4; and

FIG. 6 provides yet another embodiment, implementing a redundancy feature.

### DESCRIPTION OF THE INVENTION

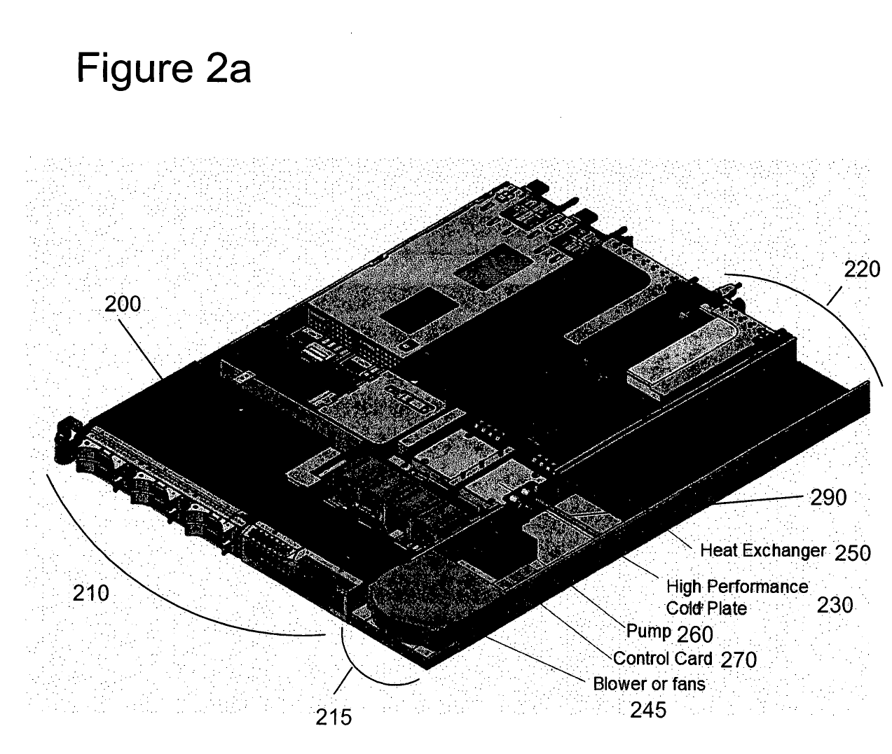

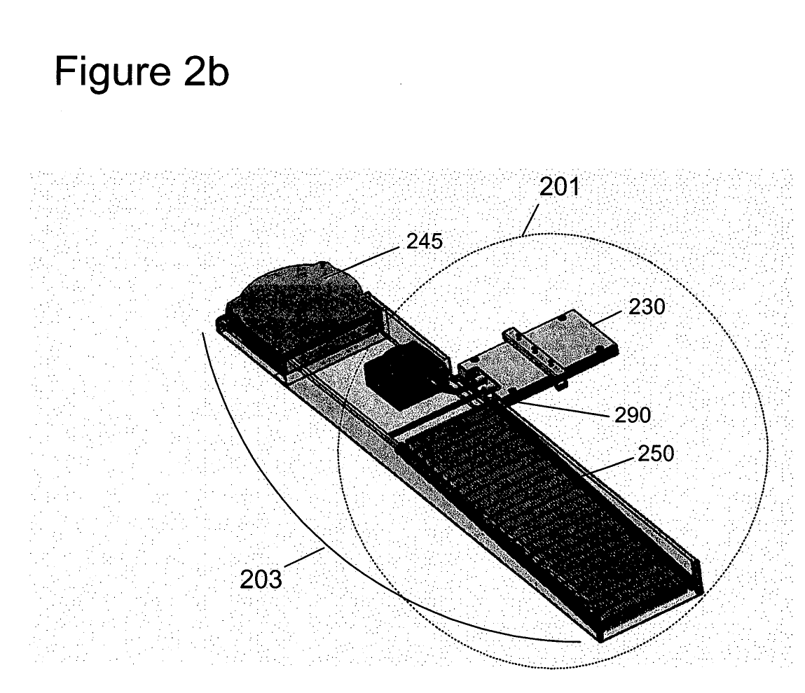

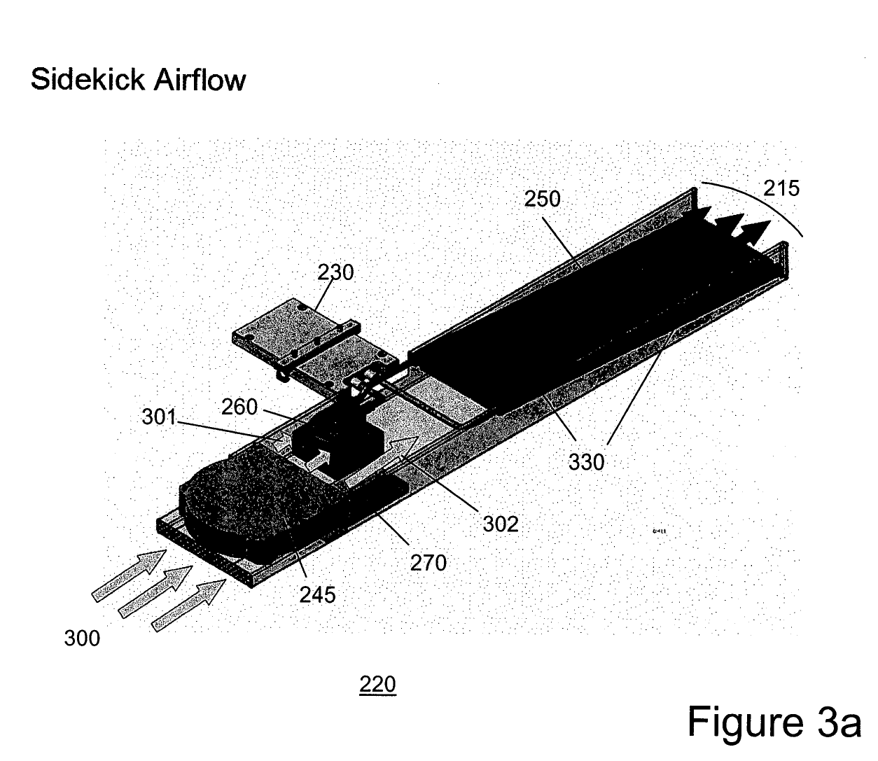

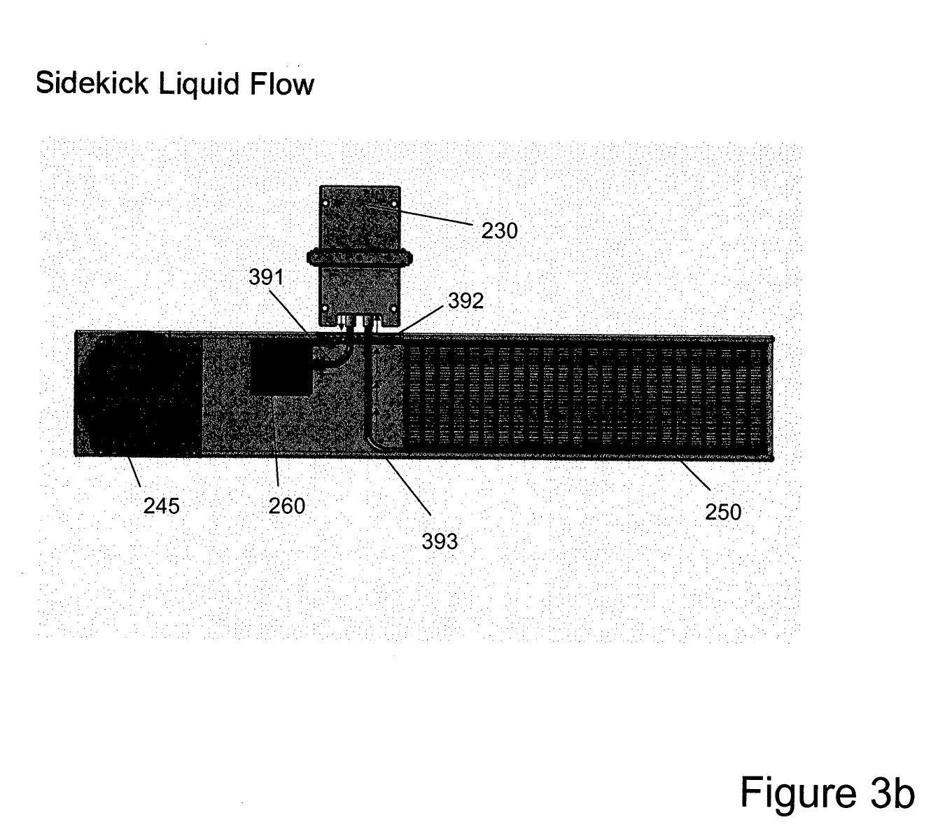

FIG. 2a is an isometric illustration of a cooling module assembly 220 as per one embodiment of the present invention. FIG. 2b, provides a more detailed look at the module 220 as provided in the embodiment of FIG. 2a. The module 220 as provided in FIGS. 2 and 3 presents a hybrid liquid and air cooled module as will be discussed in greater detail below. FIGS. 3a and 3b are each designed to respectively discuss the air and the liquid cooling features of the module 220.

As provided in FIGS. 2a and 2b, the module 220 uses a hybrid liquid and gaseous fluid cooled scheme and comprises of an auxiliary drawer 220 and a cold plate 230. The liquid and gaseous fluid, such as air (also interchangeably referred to as air cooled scheme) schemes will be better understood if examined separately as will be discussed later in conjunction with FIGS. 3a and 3b. To illustrate components of each scheme independently, FIG. 2b reflect references the liquid cooled as 201, and the air cooled portion as 203.

The liquid cooled portion 201 includes one or more cold plate(s) 230 and is thermally connected to a liquid pump 260 (hereinafter pump 260) and a heat exchanger 250, which when thermally connected forms a closed loop liquid cooling assembly. The thermal connection between the pump 260, heat exchanger 250 and the cold plate 230, can be achieved through a number of means known to those skilled in the art such as through piping 290 illustrated.

In one embodiment, as illustrated, the heat exchanger and the pump 260 are disposed over an auxiliary drawer 215, hereinafter drawer 215. The heat exchanger 250 and the auxiliary drawer 215 are in thermal contact with the cold plate 230. The heat exchanger 250 can also be fabricated such that it is an integral part of the auxiliary drawer 215.

In a preferred embodiment, as illustrated in FIGS. 2 and 3, the attached auxiliary drawer 215, is side attached, to the cold plate. In another preferred embodiment, the auxiliary drawer 215 is also side secured to the main drawer 210. In such mode(s) the module 220 may be interchangeably referred to as side module 220 or sidekick module 220.

The heat exchanger 250, whether disposed or integral to the auxiliary drawer 215, is placed on the auxiliary drawer 215 with an air moving device 245, also being disposed on the auxiliary drawer 215 (or integral to it). In one embodiment as illustrated, the heat exchanger 250 and the air moving device are disposed on opposing ends of the auxiliary drawer 215. Together the air moving device 245 and the heat exchanger 290 form the air cooled portion 201 of the module 220. In the embodiment illustrated in FIG. 2a, the air moving device shown is a blower, but a fan or other similar devices can also be used. The auxiliary drawer 215 also includes a control card 270 close to the liquid pump 260, both the pump 260 and the control card 270 are disposed between heat exchanger 250 and the air moving device 245. It should be noted that the location of the pump 260 and control card 270 is only provided by way of an example in the figures and they can be disposed anywhere on the auxiliary drawer between the heat exchanger 250 and the air moving device 245.

In one embodiment of the present invention as illustrated in the figures, the cold plate(s) 230 is further secured to the side of the auxiliary drawer 215. In the illustrated embodiment, the cold plate 230 is also disposed in the main drawer 210 area as illustrated. In a preferred embodiment, the cold plate 230 is a high performance cold plate to further enhance thermal management of the computing system environment.

In the arrangement shown in FIG. 2a, air is taken from the room by the blower 245 and pushed through the auxiliary tray or drawer 215 to remove heat from the heat exchanger 250. The pump 260 circulates liquid from the heat exchanger 250 to the cold plate 230. This fact can be better observed in reference with FIG. 3a. FIGS. 2a and 2b can be useful in understanding the workings of the present invention as provided by FIGS. 3a and 3b.

As discussed above, FIG. 3a provides an illustration of the air cooling side of the sidekick module 220 without focusing on the liquid cooled component of the module 220. The arrows provided in FIG. 3a and referenced as 300 illustrate the direction of air flow taken from the room. As illustrated, the air flows around the pump 260 (referenced by arrows as 301) and through the heat exchanger 250 as referenced by arrows 302. The direction of airflow through the heat exchanger 250 is referenced by arrows 330 in the illustration.

In a preferred embodiment of the present invention, the heat exchanger 250 can be placed substantially horizontally but at an oblique angle in reference to the horizontal plane of the auxiliary drawer 215 to further facilitate airflow such that air, depending on the angle of placement, is either directed in an upward or downward flow upon entering the heat exchanger 250.

FIG. 3b, illustrates the liquid cooled portion of the module 200 without focusing on the air cooled scheme as was already discussed. In FIG. 3b, the cold plate 230 is a liquid cooled cold plate. As illustrated in FIGS. 2a through c, piping 290 provided thermal communication between the liquid cold plate 230 and the rest of the module 220. In FIG. 3b, the piping is shown in more detailed and is shown as having a plurality of sections, 391, 392 and 393. This sectioning and arrangement of piping is only one such example and other such embodiments can be designed as is apparent to one skilled in the art.

Cooling liquid is pumped from the cold plate 230 through the pump 260 through piping 391 in the direction of the arrows. This liquid is then circulated to the heat exchanger 250 through piping section 392 in the direction of indicated arrows. Liquid flowing through the pipes and internal to the heat exchanger rejects heat to the air provided by the blower. The cooled liquid is then returned to the cold plate to extract heat from electronic devices through piping section 393, again as indicated by the direction of the arrows, thus establishing a closed liquid cooling loop. It should be noted that a variety of coolants can be used to supply the liquid air cooled portion of the module 200, as known to those skilled in the art. Some coolant examples include but are not limited to refrigerants, brine, fluorocarbon and fluorocarbon compounds, water and liquid metals and liquid metal compounds.

While the advantages provided by a hybrid liquid-air cooled module is self explanatory in terms of providing maximum thermal management, some discussion should now be conducted to better illustrate the non-thermal related advantages provided by the working of the present invention.

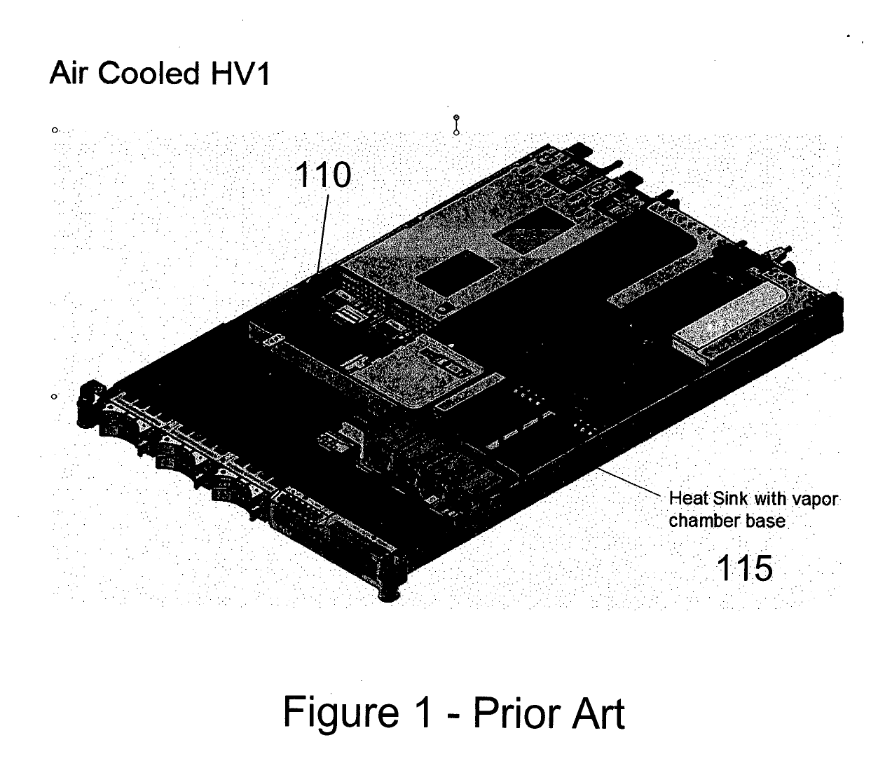

In many large computing environments, electronic components are disposed over drawers, such as drawer 110 as illustrated in prior art FIG. 1. These drawers are then disposed over one another in a rack to form a server package. In FIG. 1, a traditional 19 inch drawer 110 was illustrated to be used in typical 1U or 2 U server package arrangements. The cooling element, such as the heat sink 115, was then disposed in the main drawer 110. While the illustration of FIG. 1 showed a 19 inch drawer, in many system environments that employ larger computers and servers, it is desirous to utilize a 24 inch rack arrangement.

The present invention, provides the flexibility of extending the horizontal size of the server from the traditional 19 inch for high volume applications to the 24 inch rack width used for mid to high end servers. Consequently, not only the present design does provide extendability to future high heat load microprocessors, but it also provides simplicity of application without impacting the layout of the original server and is sized to allow the implementation of the new packages into a standard sized rack.

Referring back to FIG. 2a, the illustration of the example depicted in FIG. 2a provides for an arrangement where a 1U drawer server package is used with the liquid cooled side module, which in this case now has been extended to accommodate a 24 inch wide drawer. It should be noted that the arrangement of the present invention as illustrated is such as to take advantage of a hybrid air and liquid cooling scheme, introduced at the server level. In the embodiment as illustrated by FIG. 2a, as discussed the 19 inch drawer can be enlarged to fit in an industry standard 24 inch drawer so that the new cooling components do not disturb the electronics in the original drawer.

As was discussed in reference to the illustration of FIG. 3a (and 3b), air becomes the final sink for the heat generated by the processors as previously discussed in conjunction with the discussion of the embodiment of FIG. 2. This fact is particularly important because in the 19/24 inch width example, the sidekick module 220 performance add on for the 19 inch 1 and 2U servers will not require any new facilities at the data-center level as is the case with some prior art being currently practiced.

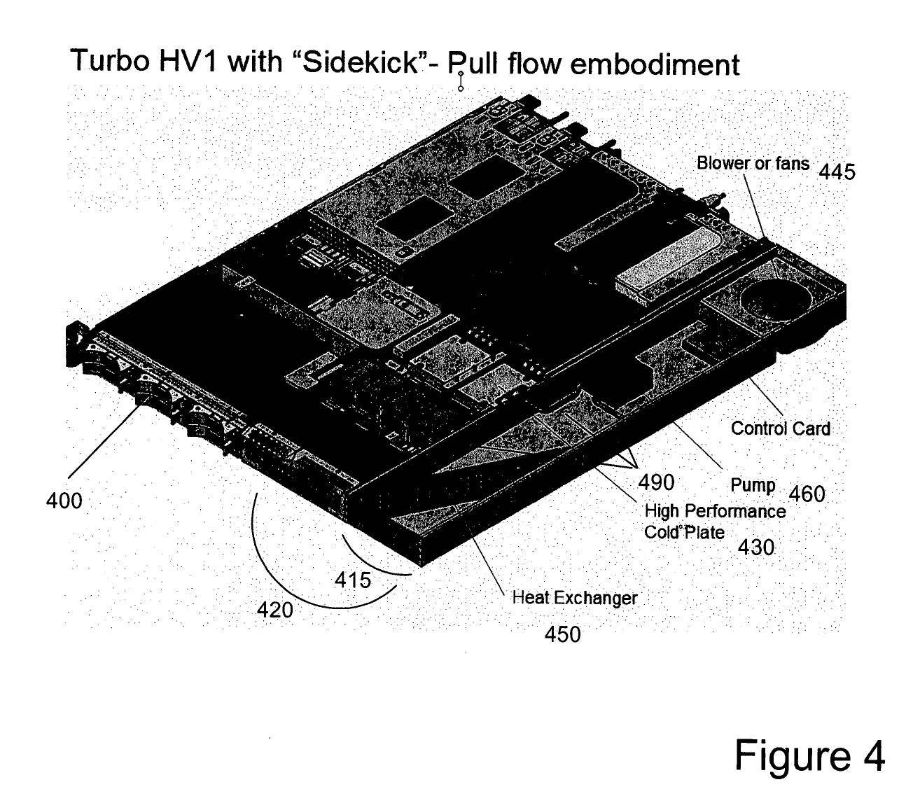

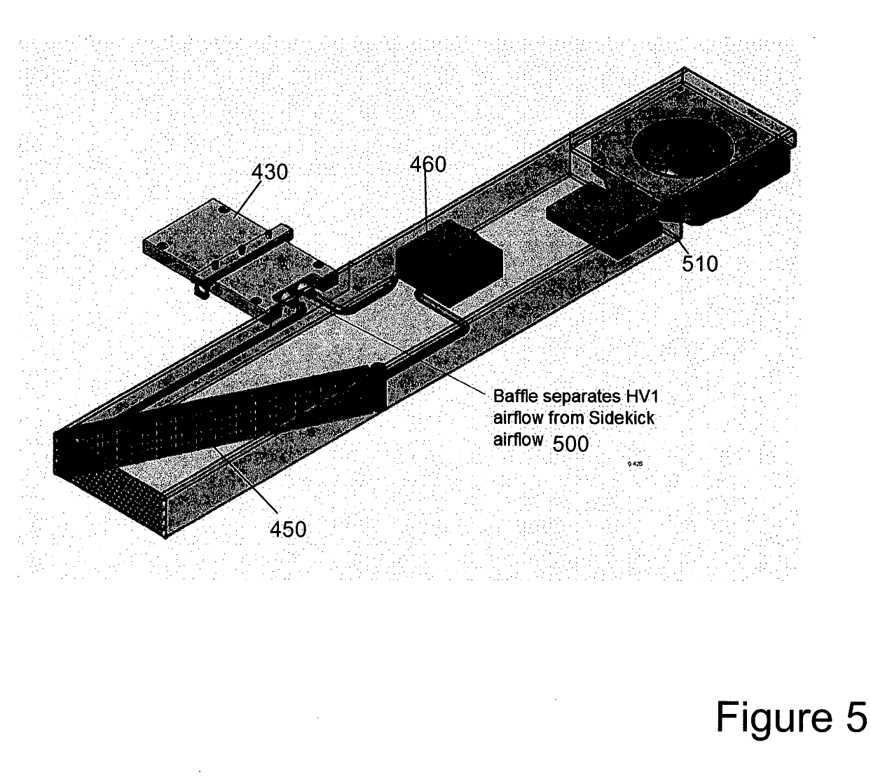

FIGS. 4 and 5 provide an alternate embodiment for the module 220 of FIGS. 2 and 3. FIG. 4, is a top down but slightly rotated view of the embodiment of FIG. 4 and provides the same kind of overall view as was discussed with the embodiment provided in conjunction with FIG. 2a through FIG. 2c.

As illustrated in FIG. 4, another embodiment for a module 420 is provided. This embodiment as was the case with the embodiment discussed with conjunction with FIG. 2a through c, also provides for a closed loop liquid system that includes one or more cold plate(s) 430 and an attached auxiliary drawer 415. As illustrated in FIG. 4 and discussed with reference to the prior embodiment, the attached auxiliary drawer 415 is preferably side attached and therefore the module 420 will be interchangeably referred to side module 420 and/or sidekick module 420.

The auxiliary drawer 415, also referred to as side-attached drawer 415, still comprises a heat exchanger 450, a liquid pump 460 and a controller card 470. However, as depicted in the illustration of FIG. 4, the heat exchanger 450 has a modified geometry. In the previously discussed embodiment, the heat exchanger 250 was substantially coplanar in geometry with the auxiliary drawer 215.

In this embodiment, however, the geometric orientation of the heat exchanger 450 is such that it is on a intersecting plane to the plane of the auxiliary drawer 215. In a preferred embodiment, the geometric orientation of the heat exchanger is orthogonal with respect to the auxiliary drawer 415. This change in geometry will enable an improved air flow process and provide space that can be used in housing other components.

As before, the auxiliary drawer 415 also includes an air moving device 445 (such as a fan) as before. In the embodiment illustrated in FIG. 4, as was the case with the previous embodiment, the air moving device shown is a blower (also referenced as 445). However, unlike the embodiment discussed in conjunction with FIGS. 2 and 3, in this embodiment the blower 445 is moved to provide a suction flow arrangement. The reason for this alternate embodiment, is to lessen the influence of blockages in the sidekick module 420, namely those caused by the pump 460, the connecting tubes/piping 490 or the control card 430, on the heat exchanger 450 and to eliminate additional heat load caused by blower 445.

It should be noted, however, that while two different embodiments and orientations were provided and discussed in conjunction with the embodiments of FIGS. 2a through c and 4, these orientations were only provided by way of example and the previous discussion of the orientation of the heat exchangers 250 and 450 should not in any way be limiting. For example the embodiment provided in FIG. 4, can have a heat exchanger that is substantially perpendicular to the drawer 450 or turned in different angles. In the embodiment of FIGS. 2a through c, the heat exchanger can also be raised, lowered, tilted or the like to accommodate different air flow arrangements. In short, many different heat exchanger orientations can be implemented selectively to address air flow needs and heat exchanger active area needs related to a particular situation as discussed in conjunction with the workings of the present invention and any discussion of a particular orientation was performed in conjunction with a preferred embodiment, for ease of understanding or both.

FIG. 5 provides a more detailed illustration of the sidekick module 450 that was previously shown in FIG. 4. FIG. 5 provides a top down view of the module 450 without the other electronic components, similar to that of the illustration of FIG. 3. In FIG. 5, the cold plate(s) 430 is shown to not to be disposed over the auxiliary drawer but is in thermal connection and disposed to a side of it. This was also the case of the example provided in the illustration of FIG. 4. In FIGS. 4 and 5, where this arrangement is being used the cold plate 430 will be disposed in the main drawer 410 area as illustrated, similar to the arrangement previously discussed in conjunction with FIG. 2. As before, in a preferred embodiment, the cold plate 430 is a high performance cold plate to further enhance thermal management of the computing environment.

FIG. 5 also provides details on other alternate embodiments that can be incorporated into different designs of the embodiments of the present invention, both those that can be incorporated into the first or alternate embodiments discussed in conjunction with FIGS. 2 and 4. The hybrid nature of the module 220 as was provided in FIG. 2 can also be duplicated by the use of similar piping 490 as provided in FIGS. 4 and 5, allowing thermal communication to be established between the cold plate 430 and other parts of the module 420.

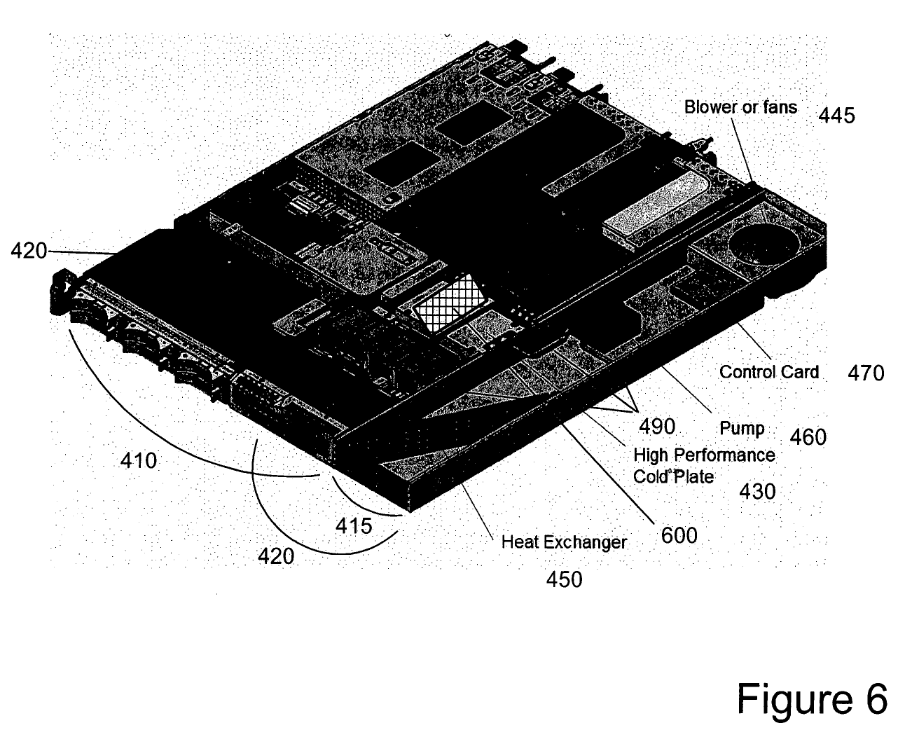

FIG. 6 is alternative embodiment of the present invention. It should be noted that while the alternative embodiment of FIG. 6 is illustrated in conjunction with that of the embodiments of FIGS. 4 and 5, however, the embodiment of FIG. 6 can be equally incorporated into the embodiment discussed in conjunction with FIGS. 2 and 3, and or other variations of the present invention.

In FIG. 6, a second heat exchanger 600 is disposed over cold plate 430. This second heat exchanger 600 is added to further improve the performance of the hybrid module. In one embodiment of the present invention, this second heat exchanger 600 is disposed over the cold plate 430 and is therefore already in thermal communication with the auxiliary drawer 415 through its placement over the cold plate 430. In other embodiments, it is possible to add a plurality of additional heat exchangers such as the one illustrated in FIG. 6. As before, the heat exchanger, such as the one illustrated in FIG. 6, may alternatively be coplanar to that of the cold plate 430, disposed at oblique angle or disposed on an intersecting plane in relation to the cold plate 430. Alternatively, in some other embodiments, additional heat exchangers may be disposed in other locations in the main drawer 410. Thermal communication may be established through placement (such as when disposed directly on the cold plate 430) of the additional heat exchanger 600 or may be provided by additional piping or other similar means as known to those skilled in the art.

The present invention, as discussed above provide for an improved cooling module that resolves the problems of prior art currently being practiced. The hybrid air and liquid cooled scheme achieves maximum performance results and introduces a cooling technology with greater heat dissipation capability that will not disturb other electronics in these computing system environments. The hybrid module of the present invention introduces superior cooling, especially to one or a plurality of microprocessors utilized in a larger computing system environment. This will allow the utilization of higher voltages and frequencies in these microprocessors, which in turn enables high-performance packages to be offered with minimal impact to customers and vendors. In addition, the present invention allows for a manner to extend a 19 inch drawer, when desired, to one that can be utilized with a 24 inch rack, a factor that will provide advantages to users of larger computing system environments.

While the preferred embodiment to the invention has been described, it will be understood that those skilled in the art, both now and in the future, may make various improvements and enhancements which fall within the scope of the claims which follow. These claims should be construed to maintain the proper protection for the invention first described.

What is claimed is:

1. A hybrid air and liquid cooling module for cooling electronic components, comprising: a closed loop liquid cooled assembly in thermal and fluid communication with an air cooled assembly; wherein said air cooled assembly is at least partially included in said liquid cooled assembly and said air cooled and said liquid cooled assembly are at least partially disposed on an auxiliary drawer, said auxiliary in turn being disposed to a side of electronic cooling components.

2. A hybrid air and liquid cooling module for cooling electronic components comprising:
a closed loop liquid cooling assembly including a heat exchanger, a liquid pump and a cold plate in thermal communication with one another; and
an air cooled assembly in thermal contact with said closed loop liquid cooling assembly, said air cooled assembly including said heat exchanger and an air moving device both disposed on said auxiliary drawer such that air can pass easily from one side of said auxiliary drawer to another side;
said liquid pump also being disposed over said auxiliary drawer between said heat exchanger and said air moving device side.

3. The hybrid module of claim 2, wherein a control card is also disposed over said auxiliary drawer.

4. The hybrid module of claim 1, wherein said cold plate is disposed to a side of said auxiliary drawer, between said heat exchanger and said air moving device.

5. The hybrid module of claim 4, wherein said cold plate is placed in a main drawer housing electronic components of a computing system and said main plate and said main drawer are secured to said auxiliary drawer.

6. The hybrid module of claim 5, wherein said cold plate is placed in a main drawer housing electronic components of a computing system and said main plate and said main drawer are secured to said auxiliary drawer.

7. The hybrid module of claim 4, wherein module is to be used in conjunction with main drawers placed on racks of a server, and said auxiliary drawer is designed such that it can allow said module to be used in conjunction with different rack diameter sizes.

8. The hybrid module of claim 2, wherein said heat exchanger is formed in an oblique angle in relation to said auxiliary drawer.

9. The hybrid module of claim 2, wherein said air moving device is a blower.

10. The hybrid module of claim 2, wherein said cold plate is a high performance cold plate.

11. The hybrid module of claim 2, wherein said heat exchanger, said pump and said cold plate are in thermal communication with one another via piping.

12. The hybrid module of claim 2, wherein said heat exchanger is placed coplanar with said auxiliary drawer.

13. The hybrid module of claim 2, wherein said heat exchanger and said auxiliary drawer are disposed on intersecting planes.

14. The hybrid module of claim 2, wherein said heat exchanger and said auxiliary drawer are disposed on orthogonal planes.

15. The hybrid module of claim 10, wherein liquid coolant is provided in said piping.

16. The hybrid module of claim 13, wherein said cold plate is placed in a main drawer housing electronic components of a computing system.

17. The hybrid module of claim 15, wherein a baffle is provided to separate said modules airflow from airflow from rest of said main drawer.

18. The hybrid module of claim 14, wherein said coolant is selected from the group consisting of refrigerants, brine, fluorocarbons and fluorocarbon compounds, water and liquid metals and liquid metal compounds.

19. A method for providing a hybrid air and liquid cooling module for cooling electronic components comprising:
forcing air through an air moving device, disposed over an auxiliary drawer of an air cooled assembly and directing it to a heat exchanger placed also disposed over said auxiliary drawer;
removing heat from electronic components by establishing thermal communication between connecting said heat exchanger to a liquid pump disposed on said auxiliary drawer and a cold plate not disposed on said auxiliary drawer in such a manner that said heat exchanger, said liquid pump and said auxiliary drawer form a closed loop liquid cooled assembly.

20. The method of claim 19, wherein said liquid pump, said cold plate and said heat exchanger are connected through piping and heat is removed from said heat exchanger by said pump circulating liquid coolants via piping between said heat exchanger and said cold plate.
